(19) United States
(12) Patent Application Publication
(10) Pub. No.: US 2004/0229558 A1
(43) Pub. Date: Nov. 18, 2004

(54) Centralized cooling system for multiple servers and other electronic devises

(76) Inventor: Frank W. Johnson, Beulah, MI (US)

Correspondence Address: Frank W. Johnson, 5785 Van Deman Place, POB 229, Beulah, MI, 49617, US

(21) Appl. No.: 10/436,413

(22) Filed: May 13, 2003

(51) Int. Cl. H05K 5/00

(52) U.S. Cl. 454/184

(57) ABSTRACT

A method of replacing the local cooling system of each electronic unit, an unfiltered fan, with one or two, separately filtered, positive pressure cooling systems for all of the units. Being positive pressure, all leaks in the system and the case, will be leaks of filtered air into the dusty computer room instead of dirty air into the equipment case. Further it is cheaper and more effective to use one or two systems rather than 10, or 20, or even 100 separate cooling systems.

Combined with a central DC power supply, which will also be more effective and less expensive, the total package will be a more reliable, and cost effective system.

### REFERENCES CITED

### US PATENT DOCUMENTS

6,523,112 Gallagher, et al, Operating system boot program and execution method

6,300,847 Gallagher, et al Backplane having transmission line ethernet bus.

6,157,534 Gallagher, et al Backplane having transmission line ethernet bus

6,078,503 Gallagher, et al Partionable Cabinet

6,023,148 Pignolet, Power management systems with redundant independent replacement battery chargers.

### STATEMENT REGARDING FEDERALLY SUPPORTED RESEARCH OR DEVELOPMENT

There was no federal support in research or development.

### BACKGOUND OF THE INVENTION

This invention is in the field of cooling multiple computer units. This invention is part of a series of changes of aggregating as many as possible of the support functions together in one place.

When PCs, disc drives, servers, and other electronic equipment were first developed, they were largely stand alone equipment. With the expansion of both individual units and the increasing use of multiple near identical units, we now have groups of units.

U.S. Pat. Nos. 6,523,112, 6,300,847, 6,157,534, 6,078,503 are all Gallagher, et all and are assigned to EMC Corporation, as is the last U.S. Pat. No. 6,023,148, Pignolet. They form a group of EMC patents that describes a cabinet holding “a data server having a plurality of hot replaceable unit modules”. Theses patents are the nearest prior art, in that they have grouped the electronic units into a group. These groups have a single cabinet, with backplane I/O connections, a central power supply, with battery back up. These patents cover definite complete group-unit in one cabinet. My patent, on the other hand, rather than having units, moves some or all of the support functions to a room or a separate area of a room, where all of the units are similar in that they have all relinquished the same support functions to the central system. This central system can have various controls and redundancies which makes the overall system much more robust.

All servers, routers, hard drives, and CPUs have functions that can be handled in common. This patent applies to the providing the cooling to each unit, from a common source, rather than having a cooling unit in each unit, or groups of units.

### BRIEF SUMMARY OF THE INVENTION

The invention describes a centralized cooling system for multiple electronic units. The system will be positive pressure, filtered, clean air. By pre-filtering the air you can reduce the size and amount of particles as much as needed, by the filters used. Further by using positive pressure, all leaks are of filtered air out of the equipment and not room air (with dust) into the equipment.

### DETAILED DESCRIPTION OF THE INVENTION

In the 1^{st} embodiment each near-identical electronic unit will slide into an equipment rack. The unit will not have no fan. Where the fan is located there will be a male tube, sized for the amount of air needed. The backplane rack will have a female air connection. The case of the unit and the unit will be designed for the best air flow of positive pressure, filtered air. The necessary I/O connections will be at the back of the unit. They may be plugs that fit into the rack, or cords. The female air connector in the rack will seal when the male connector is withdrawn.

The rack will have all of the necessary connectors, cable channels, etc. There will be, in the room set aside for this system, two interconnected air supply systems. Each of these systems will be able to carry the whole load if the other is inoperative. They will be positive pressure and filtered.

By using positive pressure, filtered air, you do not recirculate any of the environmental dust. The air leaks in the case etc. leak clean air out not contaminated air in. In this way you can decrease the dust in the individual unit as much as you want. It should be particularly good for hard disc drives and systems that the moving parts, such as electromechanical optic switches or other devices susceptible to dust.

In the 2^{nd} embodiment, different electronic units may be used. These may be servers, PCs, hard drives, or other functions requiring cooling. In that case the connections on the backplane of air, I/O, and power will have to be arranged for each unit, by varying the backplane connections.

The 3^{rd} embodiment will be basically the same except that the power to the devises will be DC from a central AC/DC converter, that will also be duplicated, with the proper back-up controls. In this embodiment the power will be delivered by cable or a mating plug in the back board. This is described in another patent application. In this embodiment you need less air, as you do not have to cool the AC/DC converter. Further you have a simpler, more reliable system, because the central control will provide redundancy and monitoring at a reduced cost.

I claim:

1. A centralized cooling system for multiple electronic units where:
a. the centralized cooling system provides all of the cooling air to the individual units;
b. the cooling system is positive pressure, thus preventing any dusty room air from entering the individual units, and
c. where the air is filtered by one or more air filters, that provide redundancy, and provides the positive pressure air through a female fitting for each unit, that seals when the male fitting on the individual unit is withdrawn and
d. the individual units will have no fans and
e. the individual units will be designed with the air outlets and the component placements for the most effective flow of the positive filtered air, and
f. the units may have plug-in connectors that match the rack and connect when the unit is pushed into place, and
g. the units may have no individual power supply and get their power from a central AC/DC converter, thus they would need less air flow for cooling, and
h. The AC/DC converters can be simplified as it does not have to supply the fan and
i. This further reduces the 60cycle noise in the individual unit.
